(19) United States
(12) Patent Application Publication
(10) Pub. No.: US 2017/0271493 A1
(43) Pub. Date: Sep. 21, 2017

(54) SEMICONDUCTOR DEVICE

(71) Applicant: KABUSHIKI KAISHA TOSHIBA, Tokyo (JP)

(72) Inventors: Akira YOSHIOKA, Kanazawa Ishikawa (JP); Takuo KIKUCHI, Kamakura Kanagawa (JP); Junji KATAOKA, Yokohama Kanagawa (JP); Naoharu SUGIYAMA, Yokohama Kanagawa (JP); Hung HUNG, Nonoichi Ishikawa (JP); Yasuhiro ISOBE, Kanazawa Ishikawa (JP)

(21) Appl. No.: 15/231,328

(22) Filed: Aug. 8, 2016

(30) Foreign Application Priority Data
Mar. 15, 2016 (JP) 2016051509

(51) Int. Cl. H01L 29/778; H01L 29/20

(52) U.S. Cl. CPC H01L 29/7786; H01L 29/2003

(57) ABSTRACT

A semiconductor device includes a first nitride semiconductor layer, a second nitride semiconductor layer containing aluminum located on the first nitride semiconductor layer, a third nitride semiconductor layer with an aluminum concentration higher than that of the second nitride semiconductor layer located on the second nitride semiconductor layer, a drain electrode and a source electrode provided on one of the second nitride semiconductor layer and on the third nitride semiconductor layer, and a gate electrode located between the drain electrode and the source electrode.

### CROSS-REFERENCE TO RELATED APPLICATION

This application is based upon and claims the benefit of priority from Japanese Patent Application No. 2016-051509, filed Mar. 15, 2016, the entire contents of which are incorporated herein by reference.

### FIELD

Embodiments described herein relate generally to a semiconductor device.

### BACKGROUND

In a semiconductor device including at least two kinds of nitride semiconductor layers, when a high voltage is applied between a gate electrode and a drain electrode, electrons of a two dimensional electron gas generated between the nitride semiconductor layers may be trapped at, for example, an interface between the nitride semiconductor layer and the gate insulating film. In such a case, the volume of the two dimensional electron gas decreases in order to keep the charge neutral, and as a result, a current collapse phenomenon can easily occur.

### BRIEF DESCRIPTION OF THE DRAWINGS

FIG. 1 is a cross-sectional view showing a schematic structure of a semiconductor device according to an embodiment.

FIG. 2 is a cross-sectional view showing a manufacturing process of the semiconductor device shown in FIG. 1.

FIG. 3 is a cross-sectional view showing a manufacturing process after the manufacturing process shown in FIG. 2.

FIG. 4 is a cross-sectional view showing a manufacturing process after the manufacturing process shown in FIG. 3.

FIG. 5 is a cross-sectional view showing a manufacturing process after the manufacturing process shown in FIG. 4.

FIG. 6 is a cross-sectional view showing a schematic structure of a semiconductor device according to a modified example 1.

FIG. 7 is a cross-sectional view showing a manufacturing process after the manufacturing process shown in FIG. 6.

FIG. 8 is a cross-sectional view showing a manufacturing process after the manufacturing process shown in FIG. 7.

FIG. 9 is a cross-sectional view showing a manufacturing process after the manufacturing process shown in FIG. 8.

FIG. 10 is a cross-sectional view showing a schematic structure of a semiconductor device according to a modified example 2.

FIG. 11 is a cross-sectional view showing a manufacturing process after the manufacturing process shown in FIG. 10.

FIG. 12 is a cross-sectional view showing a manufacturing process after the manufacturing process shown in FIG. 11.

FIG. 13 is a cross-sectional view showing a manufacturing process after the manufacturing process shown in FIG. 12.

FIG. 14 is a cross-sectional view showing a manufacturing process after the manufacturing process shown in FIG. 13.

FIG. 15 is a cross-sectional view showing a schematic structure of a semiconductor device according to a modified example 3.

### DETAILED DESCRIPTION

According to one embodiment, a semiconductor device includes a first nitride semiconductor layer, a second nitride semiconductor layer containing aluminum located on the first nitride semiconductor layer, a third nitride semiconductor layer with an aluminum concentration higher than that of the second nitride semiconductor layer located on the second nitride semiconductor layer, a drain electrode and a source electrode located on one of the second nitride semiconductor layer and the third nitride semiconductor layer, and a gate electrode located between the drain electrode and the source electrode.

Hereinafter, an embodiment will be described with reference to the drawings. The embodiment is not to restrict the invention.

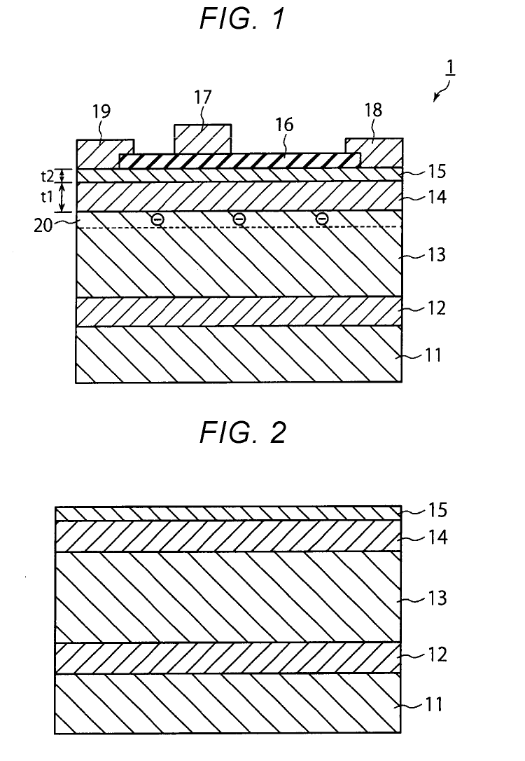

FIG. 1 is a cross-sectional view showing a schematic structure of a semiconductor device according to the embodiment. As shown in FIG. 1, a semiconductor device 1 according to the embodiment includes a substrate 11, a buffer layer 12, first, second and third nitride semiconductor layers 13 to 15, an insulating film 16, a gate electrode 17, a drain electrode 18, and a source electrode 19. The nitride semiconductor layer 13 corresponds to a first nitride semiconductor layer, the nitride semiconductor layer 14 corresponds to a second nitride semiconductor layer, and the nitride semiconductor layer 15 corresponds to a third nitride semiconductor layer.

The substrate 11 is formed of a silicon substrate. On the substrate 11, a buffer layer 12 is provided. The buffer layer 12 is a lattice relaxing layer for relaxing the mismatch of the lattice constant as between the substrate 11 and the nitride semiconductor layer 13. On the buffer layer 12, the nitride semiconductor layer 13 is provided.

The nitride semiconductor layer 13 contains undoped gallium nitride. On the nitride semiconductor layer 13, the nitride semiconductor layer 14 is provided. The nitride semiconductor layer 14 contains undoped aluminum gallium nitride. The band gap of the nitride semiconductor layer 14 is larger than that of the nitride semiconductor layer 13. On the nitride semiconductor layer 14, the nitride semiconductor layer 15 is provided.

The nitride semiconductor layer 15 contains undoped aluminum gallium nitride. The aluminum concentration of the nitride semiconductor layer 15 is higher than that of the nitride semiconductor layer 14. Further, the thickness t2 of the nitride semiconductor layer 15 is smaller than the thickness t1 of the nitride semiconductor layer 14.

The above mentioned undoped layers are film layers formed without intentionally adding dopant, not a dopant mixed layer without dopant diffused thereinto from the upper layer and the lower layer as a result of thermal treatment or the like after the film formation and/or in the manufacturing process. In other words, the undoped layer is a layer with a dopant concentration of about 1×10¹⁶/cm³ and less.

The insulating film 16 is provided on the nitride semiconductor layer 15. The insulating film 16 is formed of, for example, silicon nitride (SiN) and silicon oxide (SiO₂).

The gate electrode 17 is provided on the insulating film 16. The gate electrode 17 is formed of an alloy containing, for example, nickel (Ni) and gold (Au). The drain electrode 18 and the source electrode 19 are arranged on the nitride semiconductor layer 15 with the gate electrode 17 interposed therebetween and spaced therefrom. The drain electrode 18 and the source electrode 19 are formed of an alloy containing, for example, titanium (Ti) and aluminum (Al).

In the semiconductor device 1 configured as mentioned above, the nitride semiconductor layer 13 and the nitride semiconductor layer 14 form a heterojunction structure. The heterojunction structure generates a two dimensional electron gas 20 of high mobility at and adjacent to the interface between the nitride semiconductor layer 13 and the nitride semiconductor layer 14. The two dimensional electron gas 20 forms a current path (channel) between the drain electrode 18 and the source electrode 19. The current flowing in the current path is controlled by adjusting the voltage of the gate electrode 17. In short, the semiconductor device 1 works as a high electron mobility transistor (HEMI).

Hereinafter, with reference to FIGS. 2 to 5, a manufacturing process of the semiconductor device 1 according to the embodiment will be described.

As shown in FIG. 2, on the substrate 11, the buffer layer 12, the nitride semiconductor layer 13, the nitride semiconductor layer 14, and the nitride semiconductor layer 15 are sequentially formed. In the embodiment, each layer is formed by epitaxial growth using, for example, the Metal Organic Chemical Vapor Deposition (MOCVD) method.

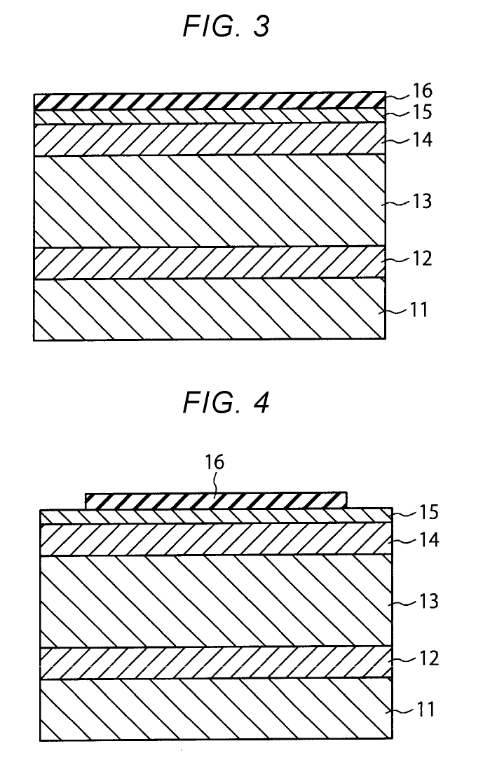

Then, as shown in FIG. 3, the insulating film 16 is formed on the nitride semiconductor layer 15. In the embodiment, the insulating film 16 is formed on the nitride semiconductor layer 15, for example, using the Plasma Enhanced Chemical Vapor Deposition (PECVD) method. Thereafter, as shown in FIG. 4, an end portion of the insulating film 16 is removed, for example, by wet etching or dry etching.

Then, as shown in FIG. 5, the drain electrode 18 and the source electrode 19 are simultaneously formed on the exposed nitride semiconductor layer 15 resulting from the etching of the insulating film 16, for example, using the vacuum deposition method and the lift-off method. Further, by adding a thermal treatment of about 700° C., the drain electrode 18 and the source electrode 19 can be in ohmic contact with the nitride semiconductor layer 15.

At the end, returning to FIG. 1, the gate electrode 17 is formed on the insulating film 16, for example, using the vacuum deposition method and the lift-off method. Here, the gate electrode 17 is provided between the drain electrode 18 and the source electrode 19.

According to the semiconductor device 1 of the embodiment as mentioned above, the nitride semiconductor layer 15 is provided between the nitride semiconductor layer 14 and the insulating film 16. Therefore, when a high voltage is applied between the gate electrode 17 and the drain electrode 18, there is a possibility that a high density interface state may be generated between the nitride semiconductor layer 15 and the insulating film 16.

In the semiconductor device 1 according to the embodiment, however, the aluminum concentration of the nitride semiconductor layer 15 is higher than that of the nitride semiconductor layer 14. In short, the band gap of the nitride semiconductor layer 15 is larger than that of the nitride semiconductor layer 14. Therefore, the nitride semiconductor layer 15 works as an electron barrier, and a minimal quantity of the electrons existing in the two dimensional electron gas 20 are trapped at or adjacent to the interface between the nitride semiconductor layer 15 and the insulating film 16.

As the result, even when a high density interface state is generated between the nitride semiconductor layer 15 and the insulating film 16, the quantity of the electrons being trapped can be suppressed. Accordingly, the phenomenon of an increasing the ON resistance caused by a decrease of the two dimensional electron gas 20, or a current collapse phenomenon, are less likely to occur.

Here, when the band gap of the nitride semiconductor layer 15 is excessively larger than that of the nitride semiconductor layer 14, there is a risk of generating the two dimensional gas in the interface between the nitride semiconductor layer 14 and the nitride semiconductor layer 15. When the thickness t2 of the nitride semiconductor layer 15 is larger than the thickness t1 of the nitride semiconductor layer 14, similarly, there is a risk of generating the two dimensional gas in the interface.

Therefore, in the embodiment, the aluminum concentration of the nitride semiconductor layer 15 is set within the range in which the two dimensional gas is not generated in the interface and the thickness t2 of the nitride semiconductor layer 15 is smaller than the thickness t1 of the nitride semiconductor layer 14.

### Modification Example 1

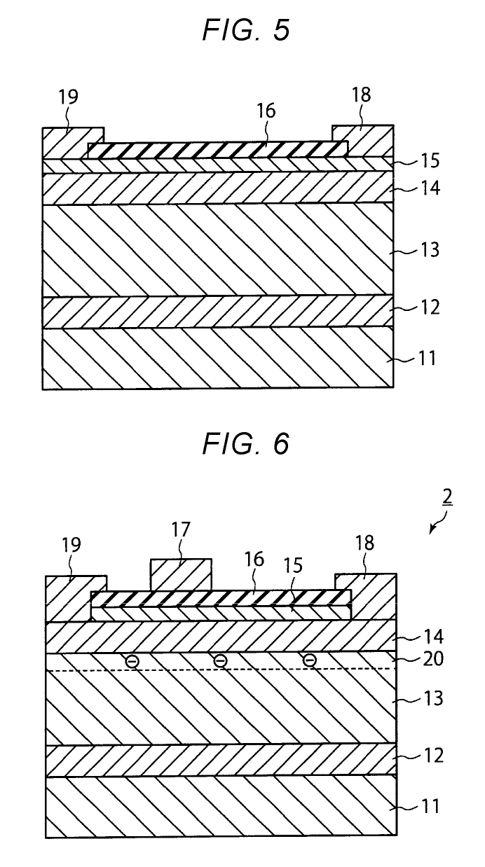

FIG. 6 is a cross-sectional view showing a schematic structure of a semiconductor device according to a modification example 1. Hereinafter, the same reference numerals are attached to the same components as those of the above mentioned semiconductor device 1 and the detailed description thereof is omitted.

As shown in FIG. 6, in a semiconductor device 2 according to this modification example, the formed area of the nitride semiconductor layer 15 is substantially the same as that of the insulating film 16.

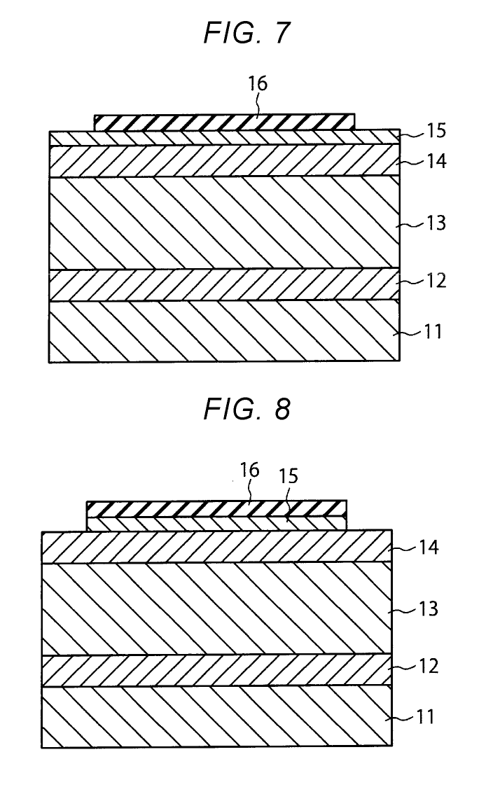

Hereinafter, the manufacturing process of the semiconductor device 2 according to this modification example will be described with reference to FIGS. 7 to 9. Of the manufacturing processes of the semiconductor device 2 according to the modification example, the process of forming the nitride semiconductor layer 13 to the nitride semiconductor layer 15 (refer to FIG. 2) and the process of forming the insulating film 16 (refer to FIG. 3) are the same as those of the above mentioned semiconductor device 1. Therefore, the description of the process is omitted and the other remaining processes will be described.

As shown in FIG. 7, also in this modification example, the end portion of the insulating film 16 is removed using wet etching or dry etching. Then, in this modification example, the end portion of the nitride semiconductor layer 15 is removed by dry etching using the insulating film 16 as a mask as shown in FIG. 8. As a result, the formed area of the nitride semiconductor layer 15 is substantially identical to the formed area of the insulating film 16.

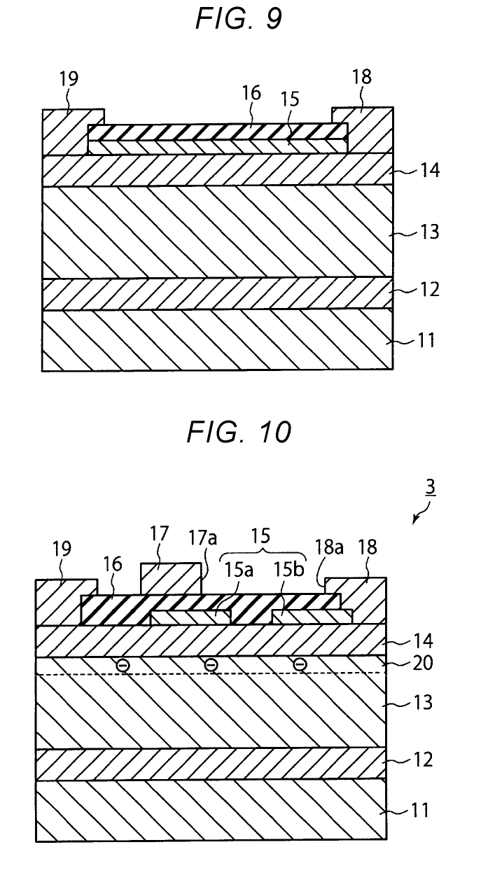

Then, as shown in FIG. 9, the drain electrode 18 and the source electrode 19 are formed on the exposed nitride semiconductor layer 14 resulting from the etching of the nitride semiconductor layer 15. Also in the modified example, the drain electrode 18 and the source electrode 19 are formed simultaneously, for example, using the vacuum deposition method and the lift-off method. Further, by adding a thermal treatment of about 700° C., the drain electrode 18 and the source electrode 19 can be in ohmic contact with the nitride semiconductor layer 14.

Returning to FIG. 6, the gate electrode 17 is then formed on the insulating film 16. Also in the modified example, the gate electrode 17 is formed on the insulating film 16, for example, using the vacuum deposition method and the lift-off method.

According to the semiconductor device 2 in the modification example as described above, the nitride semiconductor layer 15 is formed on the upper surface of the nitride semiconductor layer 14 only in the area facing the bottom surface of the insulating film 16 and between the gate electrode 17 and the drain electrode 18. In short, the nitride semiconductor layer 15 having a high band gap property is formed in the area where current collapse can easily occur.

Accordingly, the nitride semiconductor layer 15 works as the barrier of electrons, similarly to the above mentioned semiconductor device 1; therefore, fewer of the electrons are trapped at the interface between the nitride semiconductor layer 15 and the insulating film 16 from the two dimensional electron gas 20. As the result, the current collapse phenomenon is harder to occur.

### Modified Example 2

FIG. 10 is a cross-sectional view showing a schematic structure of a semiconductor device according to a second modification example. Hereinafter, the same reference numerals are attached to the same components as those of the above mentioned semiconductor device 1 and the detailed description thereof is omitted.

As shown in FIG. 10, in a semiconductor device 3 according to this modification example, the nitride semiconductor layer 15 includes a first portion 15a and a second portion 15b. The first portion 15a is formed in the area under an end portion 17a of the gate electrode 17 at the drain electrode 18 side thereof and extends therefrom in the direction of the drain electrode 18, while the second portion 15b is formed in the area under an end portion 18a of the drain electrode 18 at the gate electrode 17 side thereof and extends therefrom toward the gate electrode. Here, the nitride semiconductor layer 15 may include one of the first portion 15a and the second portion 15b.

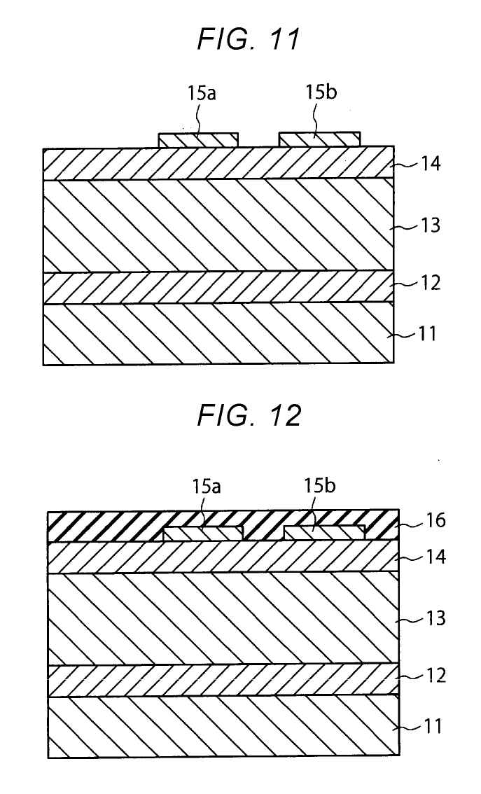

Hereinafter, the manufacturing process of the semiconductor device 3 according to this modification example will be described with reference to FIGS. 11 to 14. Of the manufacturing processes of the semiconductor device 3 according to this modification example, the process of forming the nitride semiconductor layer 13 to the nitride semiconductor layer 15 (refer to FIG. 2) is the same as that of the above mentioned semiconductor device 1. Here, the description of these processes is omitted and the remaining process will be described.

As shown in FIG. 11, in this modification example, the portion of the nitride semiconductor layer 15 formed on the nitride semiconductor layer 14 other than the first portion 15a and the second portion 15b is removed by dry etching.

Then, as shown in FIG. 12, the insulating film 16 is formed on the nitride semiconductor layer 14 to cover the first portion 15a and the second portion 15b. Also in this modification example, the insulating film 16 is formed, for example, using the PECVD method.

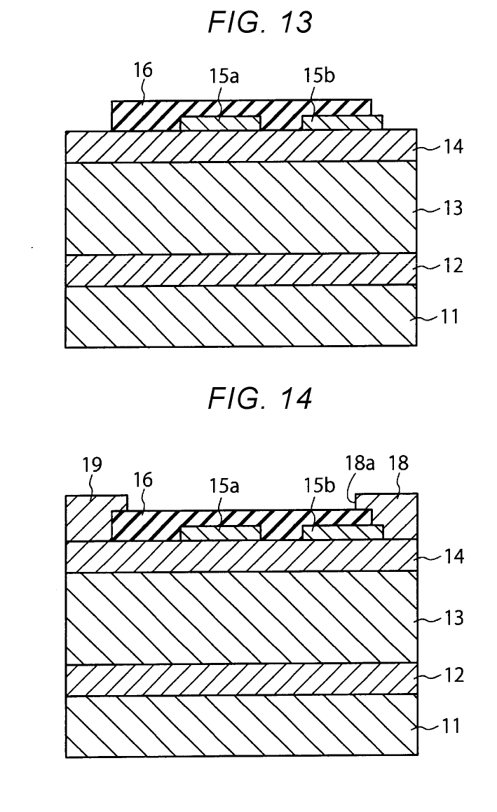

Then, as shown in FIG. 13, the end portions of the insulating film 16 are removed by wet etching or dry etching. Then, as shown in FIG. 14, the drain electrode 18 and the source electrode 19 are formed on the exposed nitride semiconductor layer 14 resulting from the etching of the insulating film 16. In this modification example, the drain electrode 18 is formed so that the end portion 18a thereof can be positioned above the second portion 15b.

Also in this modification example, the drain electrode 18 and the source electrode 19 are formed simultaneously, for example, using the vacuum deposition method and the lift-off method. Further, by adding a thermal treatment of about 700° C., the drain electrode 18 and the source electrode 19 can be in ohmic contact with the nitride semiconductor layer 14.

Returning to FIG. 10, the gate electrode 17 is then formed on the insulating film 16. In this modification example, the gate electrode 17 is formed so that the end portion 17a thereof is located above the first portion 15a. Also in this modification example, the gate electrode 17 is formed on the insulating film 16, for example, using the vacuum deposition method and the lift-off method.

According to the semiconductor device 3 in this modification example, the nitride semiconductor layer 15 is formed at least in the area under the end portion 17a of the gate electrode 17 and in the area under the end portion 18a of the drain electrode 18. Electric field intensity is easily concentrated in the end portion 17a of the gate electrode 17 and the end portion 18a of the drain electrode 18. Therefore, the area under the end portion 17a and the area under the end portion 18a are the areas where the trap electrons are easily generated, in short, the current collapse phenomenon easily happens.

Therefore, in this modification example, the first portion 15a having a high band gap property is formed in the area under the end portion 17a and similarly to the first portion 15a, the second portion 15b having a high band gap property is formed in the area under the end portion 18a. As a result, the area of forming the nitride semiconductor layer 15 can be reduced to the minimum required area for avoiding the current collapse phenomenon.

### Modification Example 3

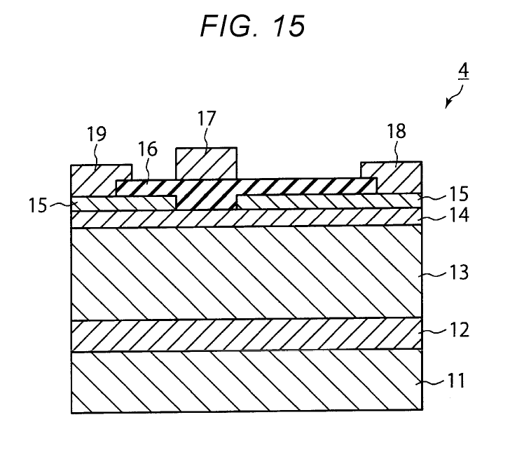

FIG. 15 is a cross-sectional view showing a schematic structure of a semiconductor device according to a third modification example. Hereinafter, the same reference numerals are attached to the same components as those of the above mentioned semiconductor device 1 and the detailed description thereof is omitted.

As shown in FIG. 15, in a semiconductor device 4 according to this modification example, the insulating film 16 is formed to extend between the upper surface of the nitride semiconductor layer 14 and the bottom surface of the gate electrode 17 in the area thereof below the gate electrode, and the nitride semiconductor layer 15 is not formed in this area. In short, the nitride semiconductor layer 15 is formed over the nitride semiconductor layer 14 between the source and drain electrodes but not in the area under the bottom surface of the gate electrode 17.

Hereinafter, the manufacturing process of the semiconductor device 4 according to the third modification example will be briefly described. Here, a process different from that for forming the above mentioned modification example 2 will be described. In the third modification example, after the nitride semiconductor layer 15 is formed on the whole top surface of the nitride semiconductor layer 14, the portion thereof which would underlie the bottom surface of the gate electrode 17 is removed by dry etching. Thereafter, the insulating film 16 is formed to cover the top surface of the exposed nitride semiconductor layer 14 resulting from the removal of the portion of the nitride semiconductor layer 15 underlying the gate electrode position, and the remaining upper surface of the nitride semiconductor layer 15. Then, similarly to the second modification example, the drain electrode 18 and the source electrode 19 are formed and at the opposed ends, and the gate electrode 17 is formed over the area where the portion of the third nitride semiconductor layer 15 was removed.

In the semiconductor device 4 according to the third modification example, if the nitride semiconductor layer 15 is formed in the area facing the bottom surface of the gate electrode 17, the carrier concentration would increase and the threshold voltage would decrease. In this case, the semiconductor device 4 would be difficult to turn off.

In the third modification example, by restricting the area of forming the nitride semiconductor layer 15 to the area excluding the area facing the bottom surface of the gate electrode 17, a decrease in the threshold voltage is suppressed. Even if restricting the area of forming the nitride semiconductor layer 15, the nitride semiconductor layer 15 is formed at least between the gate electrode 17 and the drain electrode 18. In short, the nitride semiconductor layer 15 is formed in the area where the current collapse easily occurs.

Accordingly, the third modification example can avoid the generation of the current collapse phenomenon while suppressing the influence on the switching property.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first nitride semiconductor layer;
a second nitride semiconductor layer on the first nitride semiconductor layer and including aluminum;
a third nitride semiconductor layer on the second nitride semiconductor layer and having an aluminum concentration greater than that of the second nitride semiconductor layer;
an insulating layer on the third nitride semiconductor layer;
a source electrode contacting at least one of the second nitride semiconductor layer and the third semiconductor layer;
a drain electrode contacting at least one of the second nitride semiconductor layer and the third nitride semiconductor layer, a portion of the drain electrode being in contact with and on an upper surface of the insulating layer, a portion of the insulating layer being between the third nitride semiconductor layer and the portion of the drain electrode; and
a gate electrode between the drain electrode and the source electrode.

2. The semiconductor device of claim 1, wherein the drain electrode and the source electrode are in ohmic contact with at least one of the second nitride semiconductor layer and the third nitride semiconductor layer.

3. The semiconductor device of claim 1, wherein:
the source electrode and the drain electrode are in contact with the third nitride semiconductor layer;
the third nitride semiconductor layer includes an opening therethrough extending to the second nitride semiconductor layer;
the insulating layer fills the opening; and
the gate electrode is on the insulating layer above the opening.

4. The semiconductor device of claim 1, wherein:
the third nitride semiconductor layer includes an opening therethrough extending to the second semiconductor layer;
the insulating layer fills the opening; and
the gate electrode is on the insulating layer above the third nitride semiconductor layer.

5. The semiconductor device of claim 1, wherein:
the source electrode and the drain electrode are in contact with the second nitride semiconductor layer; and
the third nitride semiconductor layer extends from the source electrode to the drain electrode.

6. The semiconductor device of claim 1, wherein the thickness of the third nitride semiconductor layer is less than the thickness of the second nitride semiconductor layer.

7. The semiconductor device of claim 1, wherein a two dimensional electron gas forms at the interface of the first and second nitride semiconductor layers and not at the interface of the second and third nitride semiconductor layers.

8. A semiconductor device comprising:
a first nitride semiconductor layer;
a second nitride semiconductor layer on the first nitride semiconductor layer and including aluminum;
a third nitride semiconductor layer on the second nitride semiconductor layer and including aluminum, wherein a thickness of the third semiconductor layer is less than a thickness of the second semiconductor layer;
an insulating layer on the third nitride semiconductor layer;
a source electrode contacting at least one of the second nitride semiconductor layer and the third semiconductor layer;
a drain electrode contacting at least one of the second nitride semiconductor layer and the third nitride semiconductor layer, a portion of the drain electrode being in contact with and on an upper surface of the insulating layer, a portion of the insulating layer being between the third nitride semiconductor layer and the portion of the drain electrode; and
a gate electrode located between the drain electrode and the source electrode.

9. The semiconductor device of claim 8, wherein the drain electrode and the source electrode are in ohmic contact with at least one of the second nitride semiconductor layer and the third nitride semiconductor layer.

10. The semiconductor device of claim 8, wherein:
the source electrode and the drain electrode are in contact with the third nitride semiconductor layer;
the third nitride semiconductor layer includes an opening therethrough extending to the second nitride semiconductor layer;
the insulating layer fills the opening; and
the gate electrode is on the insulating layer above the opening.

11. The semiconductor device of claim 8, wherein:
the third nitride semiconductor layer includes an opening therethrough extending to the second semiconductor layer;
the insulating layer fills the opening; and
the gate electrode is on the insulating layer above the third nitride semiconductor layer.

12. The semiconductor device of claim 8, wherein:
the source electrode and the drain electrode are in direct contact with the second nitride semiconductor layer; and
the third nitride semiconductor layer extends between the source electrode and the drain electrode.

13. The semiconductor device of claim 8, wherein an aluminum concentration of the third nitride semiconductor layer is greater than an aluminum concentration of the second nitride semiconductor layer.

14. The semiconductor device of claim 8, wherein a two dimensional electron gas forms at the interface of the first and second nitride semiconductor layers and not at the interface of the second and third nitride semiconductor layers.

15. A semiconductor device comprising:
a first nitride semiconductor layer;
a second nitride semiconductor layer on the first nitride semiconductor layer and having a band gap larger than that of the first nitride semiconductor layer;
a third nitride semiconductor layer on the second nitride semiconductor layer and having with a band gap larger than that of the second nitride semiconductor layer;
an insulating layer on the third nitride semiconductor layer;
a source electrode contacting at least one of the second nitride semiconductor layer and the third semiconductor layer;
a drain electrode contacting at least one of the second nitride semiconductor layer and the third nitride semiconductor layer, a portion of the drain electrode being in contact with and on an upper surface of the insulating layer, a portion of the insulating layer being between the third nitride semiconductor layer and the portion of the drain electrode; and
a gate electrode between the drain electrode and the source electrode.

16. The semiconductor device of claim 15, wherein the drain electrode and the source electrode are in ohmic contact with at least one of the second nitride semiconductor layer and the third nitride semiconductor layer.

17. The semiconductor device of claim 15, wherein:
the source electrode and the drain electrode are in contact with the third nitride semiconductor layer;
the third nitride semiconductor layer includes an opening therethrough extending to the second nitride semiconductor layer;
the insulating layer fills the opening; and
the gate electrode is on the insulating layer above the opening.

18. The semiconductor device of claim 15, wherein:
the third nitride semiconductor layer includes an opening therethrough extending to the second semiconductor layer;
the insulating layer fills the opening; and
the gate electrode is on the insulating layer above the third nitride semiconductor layer.

19. The semiconductor device of claim 15, wherein:
the source electrode and the drain electrode are in contact with the second nitride semiconductor layer; and
the third nitride semiconductor layer extends from the source electrode to the drain electrode.

20. The semiconductor device of claim 15, wherein the thickness of the third nitride semiconductor layer is less than the thickness of the second nitride semiconductor layer.
